(19) United States
(12) Patent Application Publication
(10) Pub. No.: US 2026/0047100 A1
(43) Pub. Date: Feb. 12, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Hui-Lin Wang, Taipei City (TW); Che-Wei Chang, Taichung City (TW); Chen-Yi Weng, New Taipei City (TW); Ching-Hua Hsu, Kaohsiung City (TW)

(73) Assignee: UNITED MICROELECTRONICS CORP., Hsin-Chu City (TW)

(21) Appl. No.: 18/884,092

(22) Filed: Sep. 12, 2024

(30) Foreign Application Priority Data
Aug. 12, 2024 (TW) 113130114

(51) Int. Cl. H10B 61/00; G11C 11/16; H10N 50/01; H10N 50/10; H10N 50/80

(52) U.S. Cl. CPC H10B 61/00; G11C 11/161; H10N 50/01; H10N 50/10; H10N 50/80

(57) ABSTRACT

A method for fabricating a magnetoresistive random access memory (MRAM) device includes the steps of first forming a spin orbit torque (SOT) layer on a substrate, forming a magnetic tunneling junction (MTJ) on the SOT layer, forming a first cap layer on the MTJ, and then performing a first oxidation process to form a first spacer adjacent to the MTJ. Preferably, a bottom surface of the first cap layer is lower than a bottom surface of the first spacer.

### BACKGROUND OF THE INVENTION

### 1. Field of the Invention

The invention relates to a semiconductor device and method for fabricating the same, and more particularly to a magnetoresistive random access memory (MRAM) and method for fabricating the same.

### 2. Description of the Prior Art

Magnetoresistance (MR) effect has been known as a kind of effect caused by altering the resistance of a material through variation of outside magnetic field. The physical definition of such effect is defined as a variation in resistance obtained by dividing a difference in resistance under no magnetic interference by the original resistance. Currently, MR effect has been successfully utilized in production of hard disks thereby having important commercial values. Moreover, the characterization of utilizing GMR materials to generate different resistance under different magnetized states could also be used to fabricate MRAM devices, which typically has the advantage of keeping stored data even when the device is not connected to an electrical source.

The aforementioned MR effect has also been used in magnetic field sensor areas including but not limited to for example electronic compass components used in global positioning system (GPS) of cellular phones for providing information regarding moving location to users. Currently, various magnetic field sensor technologies such as anisotropic magnetoresistance (AMR) sensors, GMR sensors, magnetic tunneling junction (MTJ) sensors have been widely developed in the market. Nevertheless, most of these products still pose numerous shortcomings such as high chip area, high cost, high power consumption, limited sensibility, and easily affected by temperature variation and how to come up with an improved device to resolve these issues has become an important task in this field.

### SUMMARY OF THE INVENTION

According to an embodiment of the present invention, a method for fabricating a magnetoresistive random access memory (MRAM) device includes the steps of first forming a spin orbit torque (SOT) layer on a substrate, forming a magnetic tunneling junction (MTJ) on the SOT layer, forming a first cap layer on the MTJ, and then performing a first oxidation process to form a first spacer adjacent to the MTJ. Preferably, a bottom surface of the first cap layer is lower than a bottom surface of the first spacer.

According to another aspect of the present invention, a magnetoresistive random access memory (MRAM) device includes a spin orbit torque (SOT) layer on a substrate, a magnetic tunneling junction (MTJ) on the SOT layer, a first cap layer adjacent to the MTJ, a second cap layer adjacent to the first cap layer, and a spacer between the first cap layer and the second cap layer.

According to yet another aspect of the present invention, a magnetoresistive random access memory (MRAM) device includes a spin orbit torque (SOT) layer on a substrate, a magnetic tunneling junction (MTJ) on the SOT layer, a first cap layer adjacent to the MTJ, and a spacer adjacent to the first cap layer. Preferably, bottom surfaces of the first cap layer and the spacer are coplanar.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 illustrate a method for fabricating a MRAM device according to an embodiment of the present invention.

FIGS. 10-12 illustrate a method for fabricating a MRAM device according to an embodiment of the present invention.

### DETAILED DESCRIPTION

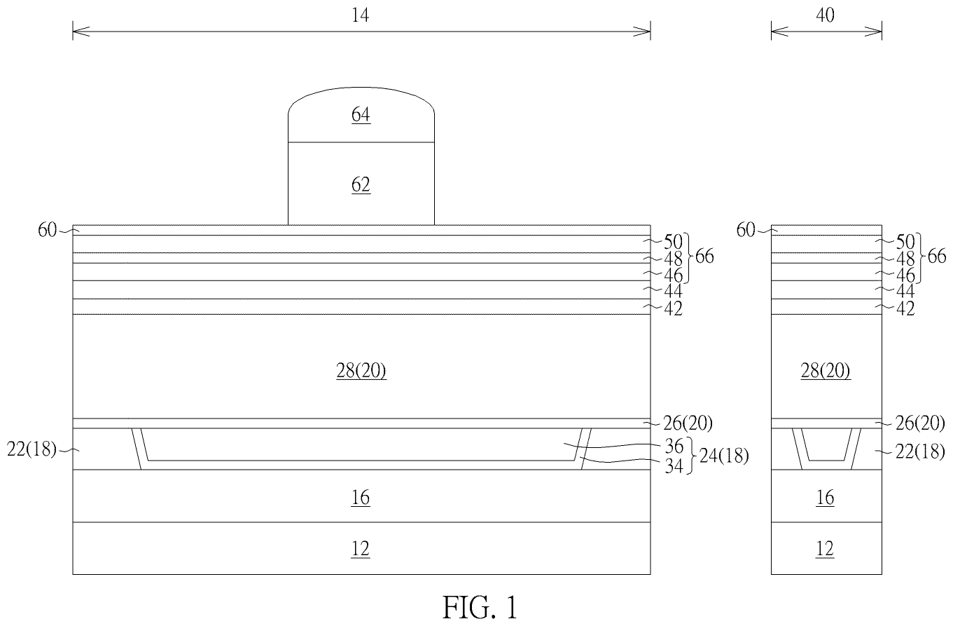

Referring to FIGS. 1-9, FIGS. 1-9 illustrate a method for fabricating a semiconductor device, or more specifically a MRAM device according to an embodiment of the present invention. As shown in FIG. 1, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a MRAM region 14 and a logic region 40 are defined on the substrate 12.

Active devices such as metal-oxide semiconductor (MOS) transistors, passive devices, conductive layers, and interlayer dielectric (ILD) layer 16 could also be formed on top of the substrate 12. More specifically, planar MOS transistors or non-planar (such as FinFETs) MOS transistors could be formed on the substrate 12, in which the MOS transistors could include transistor elements such as gate structures (for example metal gates) and source/drain region, spacer, epitaxial layer, and contact etch stop layer (CESL). The ILD layer 16 could be formed on the substrate 12 to cover the MOS transistors, and a plurality of contact plugs could be formed in the ILD layer 16 to electrically connect to the gate structure and/or source/drain region of MOS transistors. Since the fabrication of planar or non-planar transistors and ILD layer is well known to those skilled in the art, the details of which are not explained herein for the sake of brevity.

Next, metal interconnect structures 18, 20 are sequentially formed on the ILD layer 16 to electrically connect the aforementioned contact plugs, in which the metal interconnect structure 18 includes an inter-metal dielectric (IMD) layer 22 and metal interconnections 24 embedded in the IMD layer 22, and the metal interconnect structure 20 includes a stop layer 26, an IMD layer 28, and metal interconnections (not shown) embedded in the stop layer 26 and the IMD layer 28.

In this embodiment, each of the metal interconnections 24 from the metal interconnect structure 18 preferably includes a trench conductor and each of the metal interconnections (not shown) from the metal interconnect structure 20 includes a via conductor. Preferably, each of the metal interconnections 24 from the metal interconnect structures 18, 20 could be embedded within the IMD layers 22, 28 and/or stop layer 26 according to a single damascene process or dual damascene process. For instance, each of the metal interconnections 24 could further include a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In this embodiment, the metal layers 36 in the metal interconnections 24 are preferably made of copper, the IMD layers 22, 28 are preferably made of silicon oxide or ultra low-k (ULK) dielectric layer, and the stop layers 26 is preferably made of nitrogen doped carbide (NDC), silicon nitride, silicon carbon nitride (SiCN), or combination thereof.

Next, a selective bottom electrode 42, a spin orbit torque (SOT) layer 44, a MTJ stack 66, a cap layer 60, and a patterned mask or top electrode (TE) 62 are formed on the metal interconnect structure 20. In this embodiment, the formation of the MTJ stack 66 could be accomplished by sequentially depositing a free layer 46, a barrier layer 48, a reference layer (not shown), a spacer (not shown), and a pinned layer 50 on the SOT layer 44. Preferably, the free layer 46 could be made of ferromagnetic material including but not limited to for example iron, cobalt, nickel, or alloys thereof such as cobalt-iron-boron (CoFeB), in which the magnetized direction of the free layer 46 could be altered freely depending on the influence of outside magnetic field. The barrier layer 48 could be made of insulating material including but not limited to for example oxides such as aluminum oxide (AlOₓ) or magnesium oxide (MgO).

The reference layer is disposed between the barrier layer 48 and the spacer, in which the reference layer could be made of ferromagnetic material including but not limited to for example iron, cobalt, nickel, or alloys thereof such as cobalt-iron-boron (CoFeB). The spacer could be a non-magnetic layer made of non-magnetic material including but not limited to for example ruthenium (Ru), iridium (Ir), rhodium (Rh), or combination thereof.

The pinned layer 50 could be made of antiferromagnetic (AFM) material including but not limited to for example ferromanganese (FeMn), platinum manganese (PtMn), iridium manganese (IrMn), nickel oxide (NiO), or combination thereof, in which the pinned layer 50 is formed to fix or limit the direction of magnetic moment of adjacent layers. Specifically, the pinned layer 50 further includes a bottom synthetic antiferromagnetic (SAF) layer, a coupling layer, and a top SAF layer, in which the bottom SAF layer and the top SAF layer could include same or different materials while both layers could include ferromagnetic material such as cobalt (Co), nickel (Ni), platinum (Pt), palladium (Pd), or combination thereof. The coupling layer may also include materials to provide mechanical and/or crystalline structural support for the bottom SAF layer and the top SAF layer. Preferably, the coupling layer includes material that aides in this coupling including but not limited to ruthenium (Ru), tantalum (Ta), gadolinium (Gd), platinum (Pt), hafnium (Hf), or combination thereof.

Moreover, the selective bottom electrode 42 could include conductive material such as but not limited to for example Ta, TaN, Pt, Cu, Au, Al, or combination thereof, the SOT layer 44 is serving as a channel for the MRAM device as the SOT layer 44 could include metals such as tantalum (Ta), tungsten (W), platinum (Pt), or hafnium (Hf) and/or topological insulator such as bismuth selenide (BiₓSe₁₋ₓ). The cap layer 60 preferably includes metal such as Ru, and the TE 62 preferably includes conductive or dielectric material such as tantalum (Ta), tantalum nitride (TaN), titanium (Ti), titanium nitride (TiN), platinum (Pt), copper (Cu), gold (Au), aluminum (Al), or combination thereof.

In this embodiment, the formation of the patterned TE 62 could be accomplished by first forming a dielectric layer 64 made of silicon oxide on an un-patterned TE 62 and then using a patterned mask (not shown) such as patterned resist as mask to remove part of the dielectric layer 64 and part of the TE 62 through reactive ion etching (RIE) process for forming a patterned dielectric layer 64 and a patterned TE 62. The dielectric layer 64 made of silicon oxide could be selectively removed thereafter.

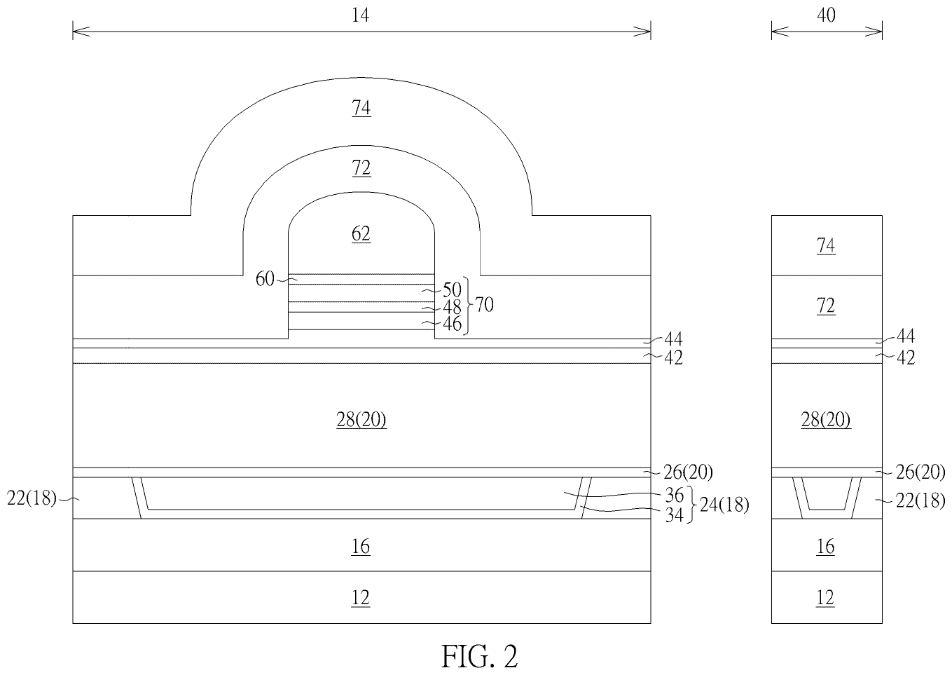

Next, as shown in FIG. 2, the patterned dielectric layer 64 or the patterned TE 62 could be used as a mask to remove part of the cap layer 60, part of the MTJ stack 66, and even part of the SOT layer 44 for forming a MTJ 70, and then a first cap layer 72 is formed on the MTJ 70 and an inter-metal dielectric (IMD) layer 74 is formed on the first cap layer 72. Preferably, the MTJ stack 66 on the logic region 40 is completely removed at this stage and during the aforementioned patterning process, parameters of the etching process are adjusted so that the top surface of the TE 62 directly on top of the MTJ 70 would form a curved surface. In this embodiment, the first cap layer 72 is preferably made of silicon nitride while the IMD layer 74 is made of silicon oxide or tetraethoxysilane (TEOS). It should be noted that when the patterned TE 62 is used to pattern the MTJ stack 66 for forming the MTJ 70, part of the SOT layer 44 could be removed at the same time so that the top surface of the remaining SOT layer 44 adjacent to two sides of the MTJ 70 is slightly lower than the top surface of the SOT layer 44 directly under the MTJ 70. According to an embodiment of the present invention, if none of the SOT layer 44 is removed during the formation of the MTJ 70, the top surface of the SOT layer 44 adjacent to two sides of the MTJ 70 would be even with the top surface of the SOT layer 44 directly under the MTJ 70. Moreover, the first cap layer 72 and the IMD layer 74 formed at this stage are preferably disposed on the MRAM region 14 and the logic region 40 at the same time.

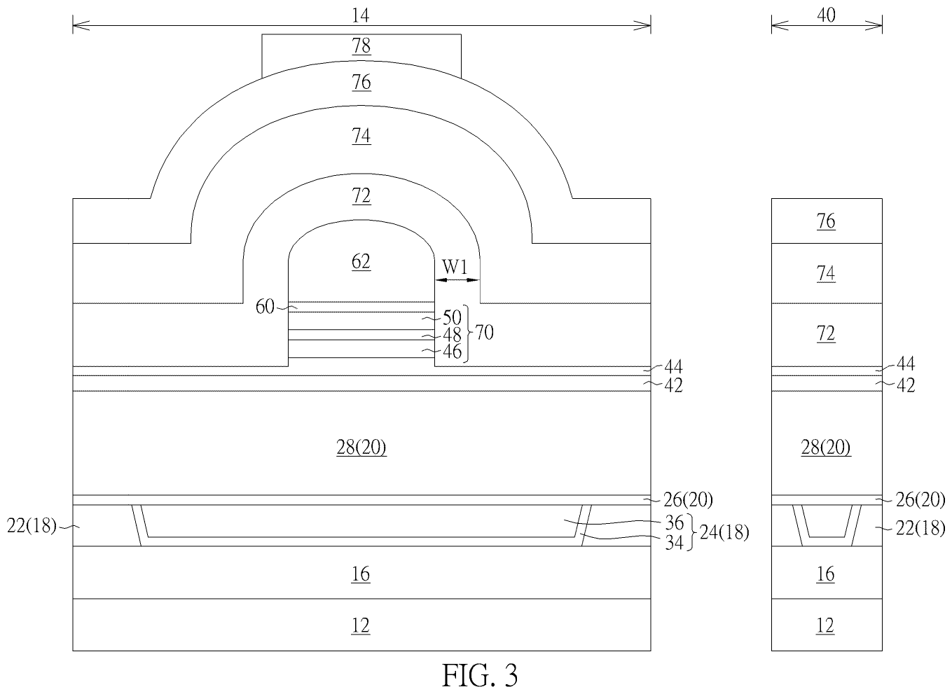

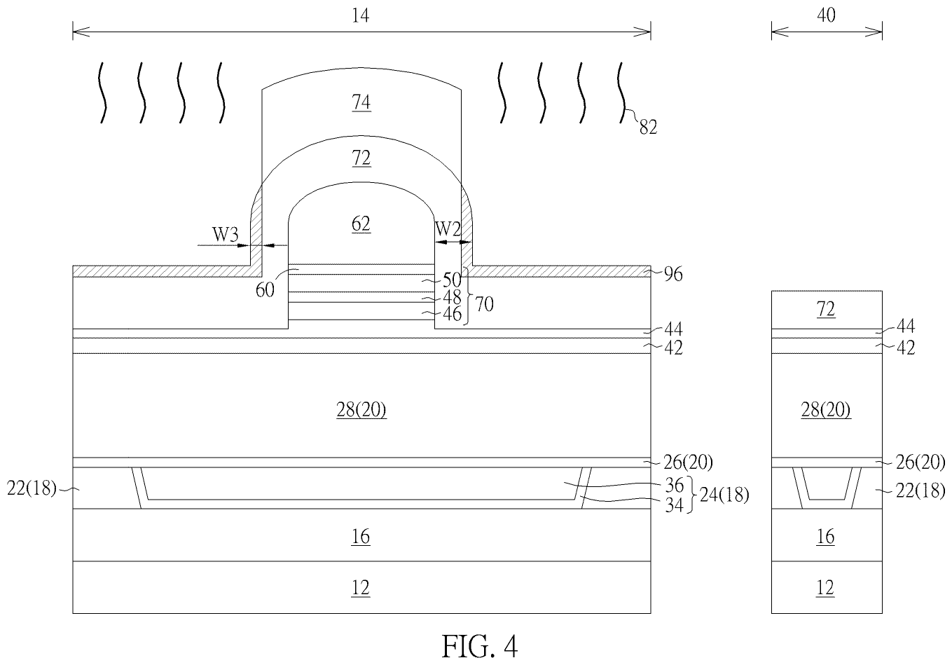

Next, as shown in FIGS. 3-4, a bottom anti-reflective coating (BARC) 76 is formed on the IMD layer 74, and then an etching process such as an ion beam etching (IBE) process is conducted by using a patterned mask 78 such as a patterned resist as mask to remove part of the BARC 76 and part of the IMD layer 74 on the MRAM region 14 and all of the BARC 76 and IMD layer 74 on the logic region 40 for exposing the surface of the first cap layer 72 underneath. Preferably, the remaining IMD layer 74 is only disposed on the MRAM region 14 while the first cap layer 72 underneath is still disposed on the MRAM region 14 and the logic region 40. The BARC 76 is then removed to expose the IMD layer 74 on the MRAM region 14. According to an embodiment of the present invention, the first cap layer 72 deposited at this stage has a width W1.

Next, a treatment process such as an oxidation process 82 is conducted by using the patterned IMD layer 74 as mask to oxidize the first cap layer 72 adjacent to two sides of the IMD layer 74 for forming a doped layer 96. Since the first cap layer 72 is preferably made of silicon nitride (SiN), the doped layer 96 formed by the oxidation process 82 preferably includes silicon oxynitride (SiON). According to an embodiment of the present invention, after the doped layer 96 is formed, the original width W1 of the first cap layer 72 is reduced to a width W2 while the doped layer 96 has a width W3, in which W2=0.5˜0.8(W1) and W3=0.3˜0.5(W2). It should also be noted that even though the treatment process conducted at this stage pertains to an oxidation process for forming the doped layer 96, according to other embodiment of the present invention, it would also be desirable to choose other means for injecting oxygen. For instance, an ion implantation process could be conducted to implant oxygen atoms into the first cap layer 72 for forming the doped layer 96, which is also within the scope of the present invention.

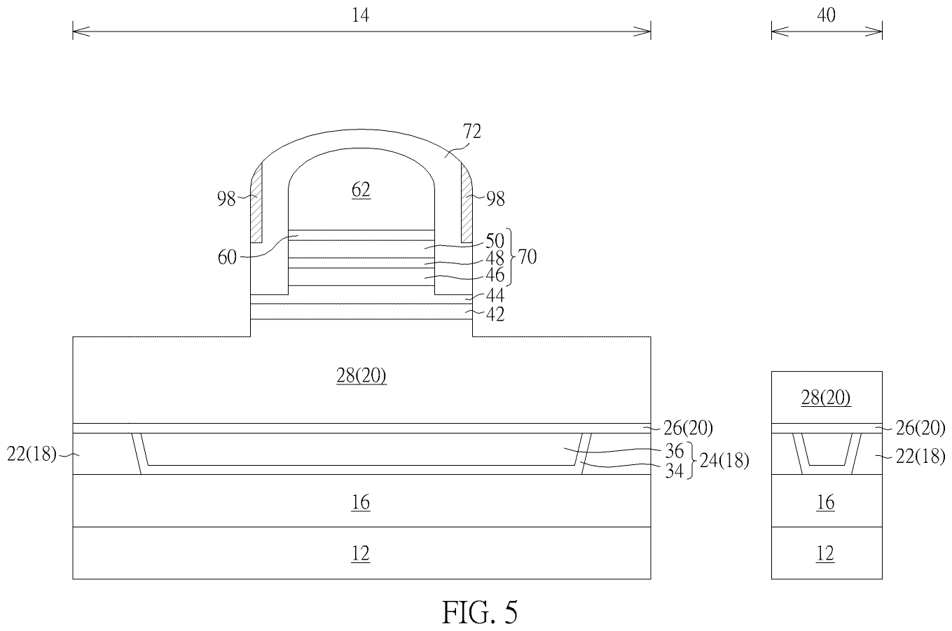

Next, as shown in FIG. 5, an etching process such as an IBE process is conducted without forming other patterned mask to remove all of the IMD layer 74, part of the doped layer 96, part of the first cap layer 72, part of the SOT layer 44, part of the bottom electrode 42, and even part of the IMD layer 28 on the MRAM region 14 and all the first cap layer 72, all the SOT layer 44, all of the bottom electrode 42, and part of the IMD layer 28 on the logic region 40. This reduces the width of the first cap layer 72, the doped layer 96, the SOT layer 44, the bottom electrode 42, and part of the IMD layer 28 on the MRAM region 14 so that the left and right sidewalls of the first cap layer 72, the doped layer 96, the SOT layer 44, the bottom electrode 42, and part of the IMD layer 28 are retracted inward and aligned with each other. The top surface of the remaining IMD layer 28 on the logic region 40 on the other hand could be slightly lower than the top surface of the IMD layer 28 on the MRAM region 14.

Preferably, the doped layer 96 extending from sidewalls of the first cap layer 72 to the IMD layer 28 adjacent to two sides of the MTJ 70 is partly removed to form a spacer 98 on sidewalls of the remaining first cap layer 72, in which both the spacer 98 and the doped layer 96 are made of SiON. It should be noted that the height of the spacer 98 could be adjusted depending on the thickness of the first cap layer 72. For instance, the bottom surface of the spacer 98 could be higher than the bottom surface of the top electrode 62, lower than the bottom surface of the top electrode 62 but higher than the top surface of the MTJ 70, lower than the top surface of the cap layer 60 but higher than the top surface of the MTJ 70, even with the bottom surface of the cap layer 60, even with the top surface of the MTJ 70, or lower than the top surface of the MTJ 70 such as lower than the top surface of the pinned layer 50 but higher than the bottom surface of the MTJ 70, which are all within the scope of the present invention.

It should be noted that even though the IBE process conducted at this stage removes part of the IMD layer 28 during the patterning of the first cap layer 72, the SOT layer 44, and the bottom electrode 42, according to other embodiment of the present invention, it would also be desirable to not removing any of the IMD layer 28 during the patterning of the first cap layer 72, the SOT layer 44, and the bottom electrode 42. In this instance, after the first cap layer 72, the SOT layer 44, and the bottom electrode 42 are patterned, the top surface of the IMD layer 28 adjacent to two sides of the first cap layer 72 or SOT layer 44 is even with the top surface of the IMD layer 28 directly under the MTJ 70, which is also within the scope of the present invention.

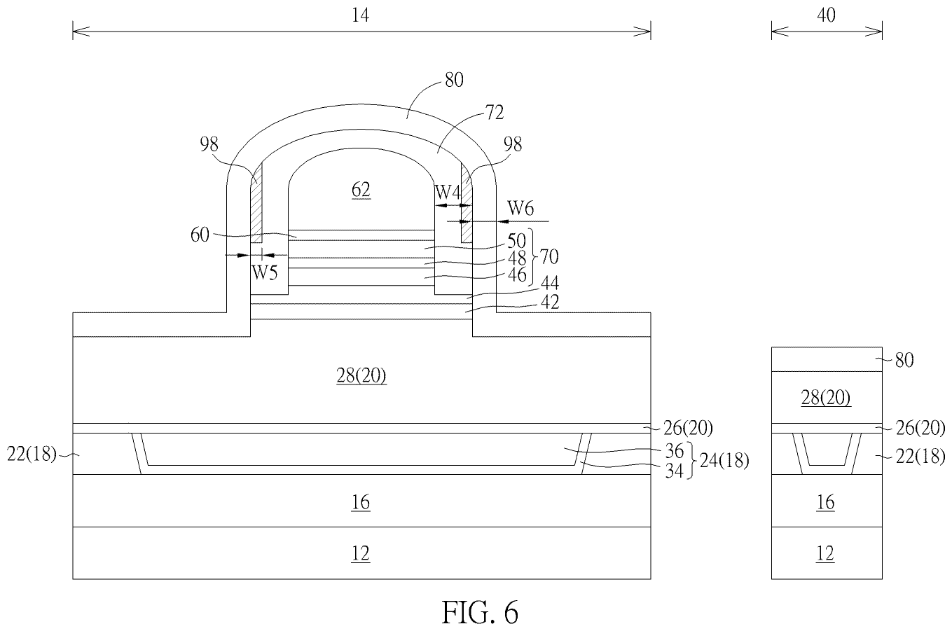

Next, as shown in FIG. 6, a second cap layer 80 is formed on the spacer 98, the first cap layer 72, and the IMD layer 28, in which the second cap layer 80 preferably covers the top surface of the first cap layer 72, sidewalls of the spacer 98, sidewalls of the first cap layer 72, sidewalls of the SOT layer 44, sidewalls of the bottom electrode 42, and the top surface of the IMD layer 28. In this embodiment, the first cap layer 72 and the second cap layer 80 are preferably made of same material such as silicon nitride (SiN). According to an embodiment of the present invention, after the second cap layer 80 is formed, the combined thickness or width of the first cap layer 72 and the spacer 98 is reduced to a width W4, the spacer 98 has a width W5, and the second cap player 80 has a width W6, in which W4=0.4˜0.7(W1), W5=0.1˜0.5(W4), and W6=0.5˜1.5(W4).

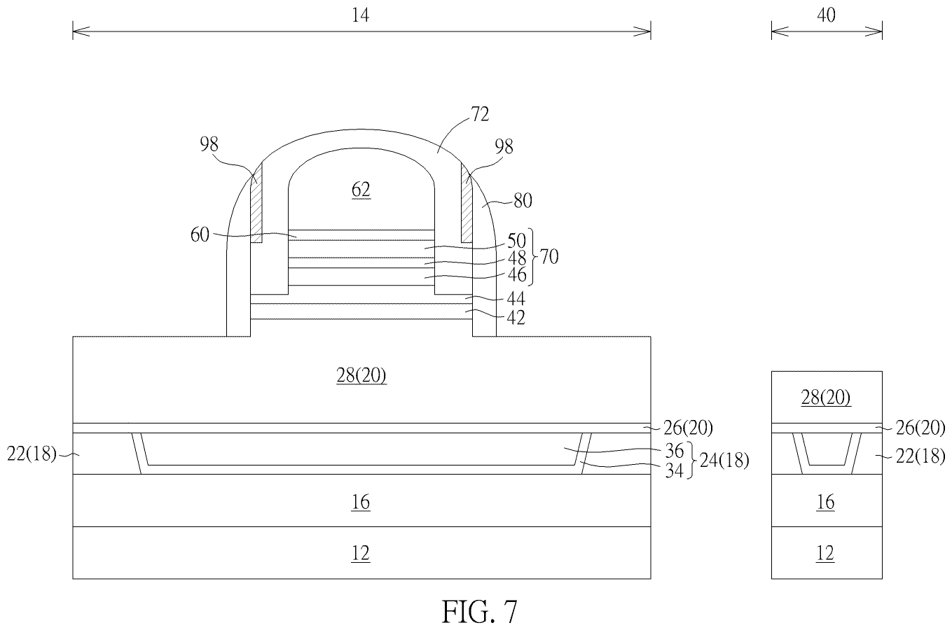

Next, as shown in FIG. 7, an etching process could be conducted without forming any patterned mask to remove part of the second cap layer 80 on the MRAM region 14 and all the second cap layer 80 on the logic region 40 and expose the top surface of the IMD layer 28. Preferably, the curved top surface of the second cap layer 80 adjacent to sidewalls of the first cap layer 72 is aligned with the curved top surface of the first cap layer 72 or the curved top surface of the first cap layer 72 is extended continuously to the curved top surface of the second cap layer 80. Moreover, the bottom surface of the second cap layer 80 is lower than the bottom surface of both the first cap layer 72 and spacer 98 while the bottom surface of the first layer 72 is also lower than the bottom surface of the spacer 98.

In this embodiment, the thickness of the first cap layer 72 is greater than the thickness of the second cap layer 80, in which the definition of thickness could be defined as the maximum distance or maximum width of each of the first cap layer 72 and second cap layer 80 extending along the X-direction. According to an embodiment of the present invention, the thickness of the second cap layer 80 is approximately 40%-80% or most preferably 60% of the thickness of the first cap layer 72. Moreover, even though both the first cap layer 72 and the second cap layer 80 are made of silicon nitride, the silicon concentration in the first cap layer 72 is preferably greater than the silicon concentration in the second cap layer 80 and the refractive index ratio of the first cap layer 72 to the second cap layer 80 is between 1.2 to 1.7. By using this recipe for adjusting the thickness as well as refractive index between the first cap layer 72 and the second cap layer 80, it would be desirable to fill more IMD layer adjacent to the MTJ in the later process thereby improving insulation capability for the device.

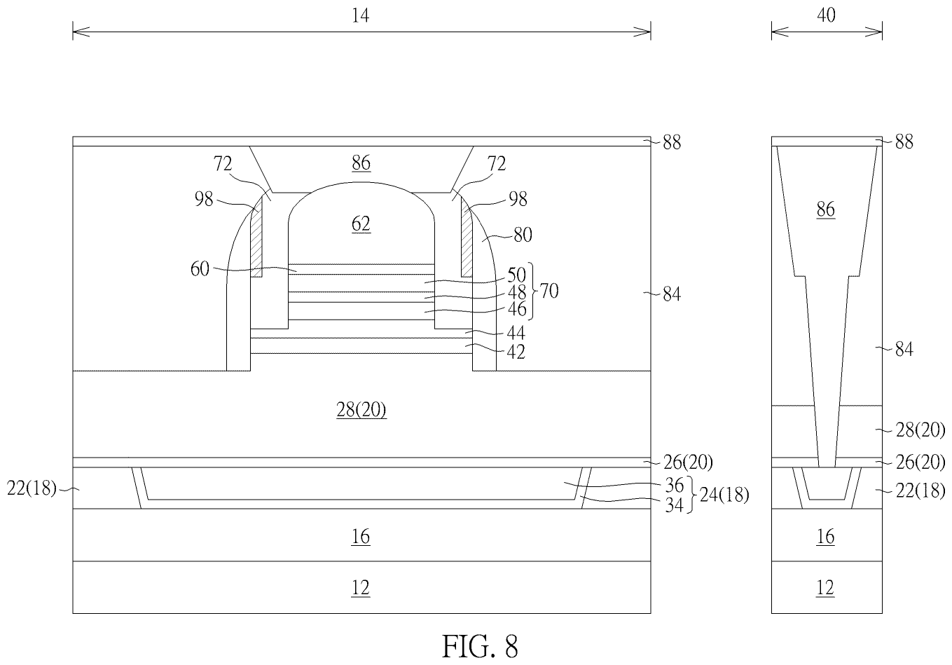

Next, as shown in FIG. 8, another IMD layer 84 is formed on the MRAM region 14 and logic region 40, a planarizing process such as chemical mechanical polishing (CMP) is conducted to remove part of the IMD layer 84, and then a pattern transfer process is conducted by using a patterned mask (not shown) to remove part of the IMD layer 84 and part of the first cap layer 72 on the MRAM region 14 and part of the IMD layer 84, part of the IMD layer 28, and part of the stop layer 26 on the logic region 40 to form contact holes (not shown) exposing the TE 62 and the metal interconnection 24 underneath and conductive materials are deposited into the contact holes afterwards. For instance, a barrier layer selected from the group consisting of titanium (Ti), titanium nitride (TiN), tantalum (Ta), and tantalum nitride (TaN) and metal layer selected from the group consisting of tungsten (W), copper (Cu), aluminum (Al), titanium aluminide (TiAl), and cobalt tungsten phosphide (CoWP) could be deposited into the contact holes, and a planarizing process such as CMP could be conducted to remove part of the conductive materials including the aforementioned barrier layer and metal layer to form metal interconnections 86 in the contact holes electrically connecting the TE 62 and the metal interconnection 24. Next, a stop layer 88 is formed on the metal interconnections 86. In this embodiment, the IMD layer 84 and the IMD layer 74 could be made of same or different material such as silicon oxide and the stop layer 88 could include silicon oxide, silicon nitride, or SiCN.

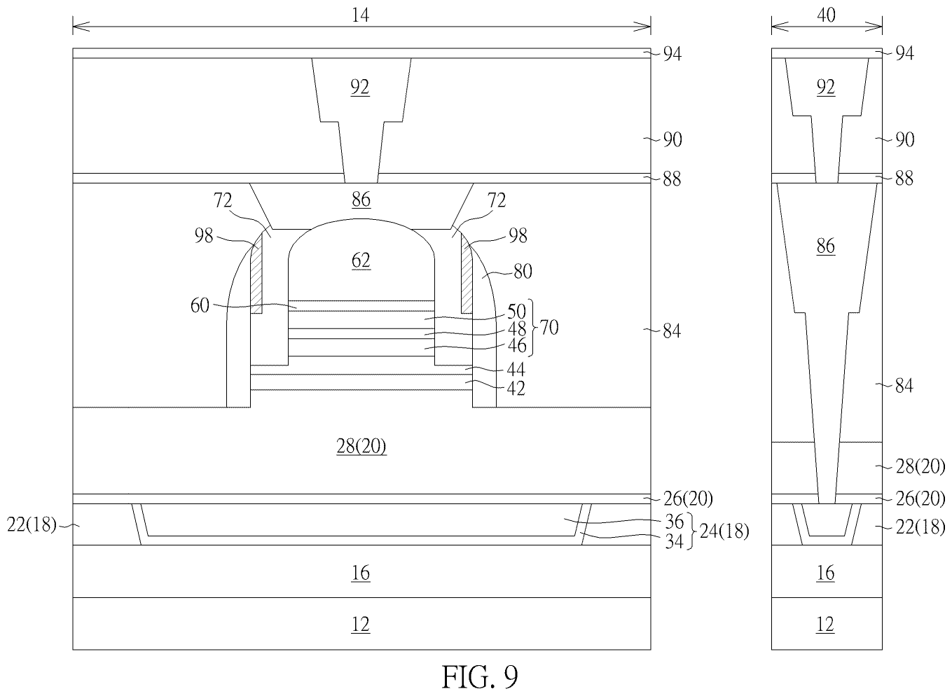

Next, as shown in FIG. 9, an IMD layer 90 is formed on the stop layer 88 of the MRAM region 14 and logic region 40, and a pattern transfer process is conducted by using a patterned mask (not shown) to remove part of the IMD layer 90 and part of the stop layer 88 for forming contact holes (not shown) exposing the metal interconnections 86 and conductive materials are deposited into the contact hole afterwards. For instance, a barrier layer selected from the group consisting of titanium (Ti), titanium nitride (TiN), tantalum (Ta), and tantalum nitride (TaN) and metal layer selected from the group consisting of tungsten (W), copper (Cu), aluminum (Al), titanium aluminide (TiAl), and cobalt tungsten phosphide (CoWP) could be deposited into the contact holes, and a planarizing process such as CMP could be conducted to remove part of the conductive materials including the aforementioned barrier layer and metal layer to form metal interconnections 92 in the contact holes electrically connecting the metal interconnections 86. Next, a stop layer 94 is formed on the metal interconnection 92. In this embodiment, the IMD layer 90 preferably includes an ultra low-k (ULK) dielectric layer including but not limited to for example porous material or silicon oxycarbide (SiOC) or carbon doped silicon oxide (SiOCH).

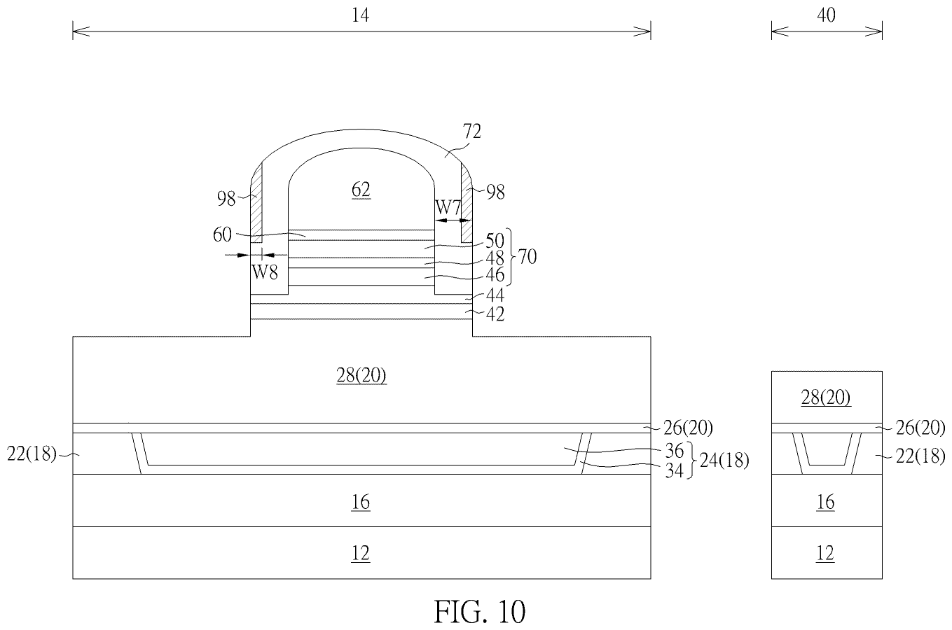

Referring to FIGS. 10-12, FIGS. 10-12 illustrate a method for fabricating a MRAM device according to an embodiment of the present invention. As shown in FIG. 10, it would be desirable to follow the processes conducted in FIGS. 1-5 to form spacer 98 on sidewalls of the first cap layer 72. In contrast to the ratio of the width W4 and width W5 disclosed in FIG. 6, the present embodiment preferably adjusts the widths of the first cap layer 72 and the spacer 98 after the oxidation process 82 is conducted to form a doped layer 96 on sidewalls of the first cap layer 72 and an etching process is carried out to remove part of the doped layer 96 for forming a spacer 98. Preferably, the combined thickness of part of the first cap layer 72 and the spacer 98 is increased to width W7 while the spacer 98 alone has a width W8, in which W7=0.6˜0.8(W1) and W8=0.1˜0.3(W7).

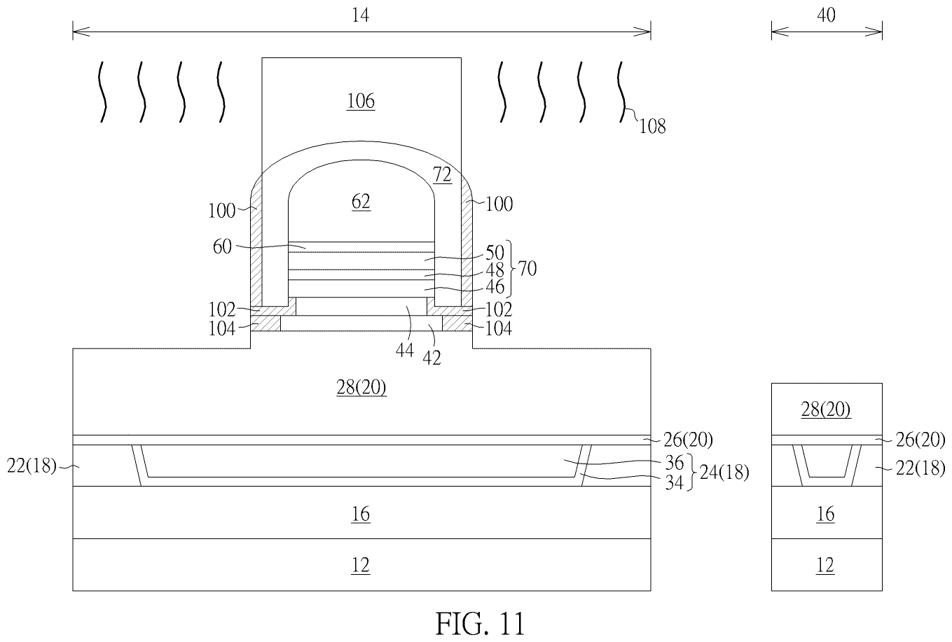

Next, as shown in FIG. 11, another oxidation process 108 could be conducted by using another patterned mask 106 as mask to inject oxygen gas and oxide sidewalls of the first cap layer 72 directly under the spacer 98. This extends the spacer 98 downward to form another spacer 100, in which the spacer 100 and the original spacer 98 are both formed by oxidizing the first cap player 72 made of SiN hence both spacers 98, 100 are made of SiON. It should be noted that the oxidation process 108 conducted at this stage not only oxidizes sidewalls of the first cap layer 72 directly under the spacer 98, but also oxidizes sidewalls of the SOT layer 44 and the bottom electrode 42 for forming doped regions 102, 104. Preferably, the composition of the doped layers 102, 104 could depend on the original material of the SOT layer 44 and bottom electrode 42. For instance, the doped regions 102 and 104 could be made of different materials while both including oxygen atoms.

Structurally, the bottom surface of the first cap layer 72 is even with the bottom surface of the spacer 100 and the spacer 100, the doped region 102 on sidewalls of the SOT layer 44, and the doped region 104 on sidewalls of the bottom electrode 42 could all have same or different widths depending on the volume of oxygen injected during the oxidation process 108. In this embodiment, the width of the spacer 100 is less than the width of the doped region 104 on sidewall of the bottom electrode 42 and the width of the doped region 104 is further less than the width of the doped region 102 on sidewall of the SOT layer 44. It should further be noted that if the SOT layer 44 adjacent to two sides of the MTJ 70 were not removed during formation of the MTJ 70, the top surface of the SOT layer 44 adjacent to two sides of the MTJ 70 would be even with the top surface of the SOT layer 44 directly under the MTJ 70 and in this instance, the bottom surface of the spacer 100 would be even with the bottom surface of the first cap layer 72 and the bottom surface of the MTJ 70.

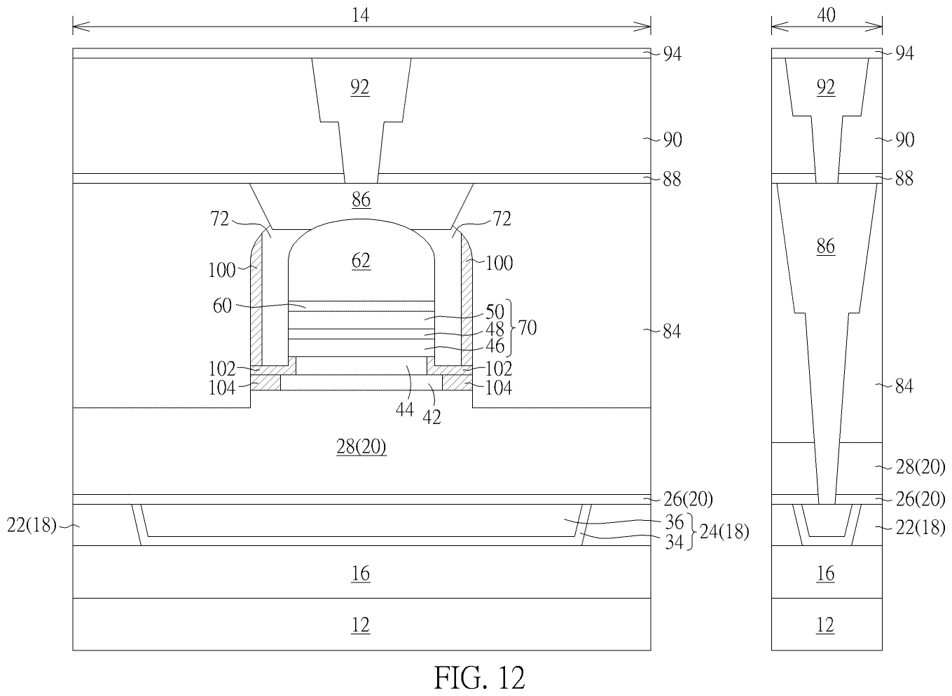

Next, as shown in FIG. 12, the formation of the second cap layer 80 could be omitted and an IMD layer 84 could be formed directly on both the MRAM region 14 and logic region 40 according to FIG. 8, a planarizing process such as CMP is conducted to remove part of the IMD layer 84, metal interconnections 86 are formed on the MRAM region 14 and logic region 40 to electrically connect the top electrode 62 and metal interconnection 24, and a stop layer 88 is formed on the metal interconnections 86 thereafter. Next, fabrication conducted in FIG. 9 could be carried out by first forming an IMD layer 90 on stop layer 88 on the MRAM region 14 and logic region 40, forming metal interconnections 92 on the MRAM region 14 and logic region 40 to electrically connect the metal interconnections 86, and then forming a stop layer 94 on the metal interconnections 92. Preferably, the materials of the metal interconnections 86, 92, the IMD layers 84, 90, and the stop layers 88, 94 could be the same as the ones disclosed in the aforementioned embodiment and the details of which are not explained herein for the sake of brevity.

Overall, the present invention discloses a method for fabricating SOT MRAM device and relating structure thereof, which first forms a SOT layer 44 and MTJ 70 on a substrate, forms a first cap layer 72 adjacent to the MTJ, and then conducts at least an oxidation process to oxidize sidewall portion of part of the first cap layer for forming a spacer adjacent to the MTJ. As disclosed in the aforementioned embodiments, the bottom surface of the spacer 98 shown in FIG. 9 could be slightly higher than the bottom surface of the first cap layer 72 or the bottom surface of the spacer 100 shown in FIG. 12 could be even with the bottom surface of the first cap layer 72. By using the above oxidation process to form a spacer adjacent to the MTJ or first cap layer, the present invention could improve SOT efficiency of the device and at the same time reduce its driving current density.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a magnetoresistive random access memory (MRAM) device, comprising:
forming a spin orbit torque (SOT) layer on a substrate;
forming a magnetic tunneling junction (MTJ) on the SOT layer;
forming a first cap layer on the MTJ; and
performing a first oxidation process to form a first spacer adjacent to the MTJ.

2. The method of claim 1, wherein the substrate comprises a MRAM region and a logic region, the method further comprising:
forming an inter-metal dielectric (IMD) layer on the substrate;
forming the SOT layer on the IMD layer;
forming a top electrode (TE) on the MTJ;
forming the first cap layer on the MTJ and the SOT layer;
performing the first oxidation process to form a doped layer in the first cap layer;
removing part of the doped layer and part of the first cap layer to form the first spacer;
forming a second cap layer on the first cap layer; and
forming an oxide layer on the second cap layer.

3. The method of claim 2, wherein a top surface of the TE comprises a curve.

4. The method of claim 2, wherein a bottom surface of the second cap layer is lower than a bottom surface of the first spacer.

5. The method of claim 2, wherein a bottom surface of the second cap layer is lower than a bottom surface of the first cap layer.

6. The method of claim 1, wherein a bottom surface of the first cap layer is lower than a bottom surface of the first spacer.

7. The method of claim 1, wherein the substrate comprises a MRAM region and a logic region, the method further comprising:
forming an inter-metal dielectric (IMD) layer on the substrate;
forming the SOT layer on the IMD layer;
forming a top electrode (TE) on the MTJ;
forming the first cap layer on the MTJ and the SOT layer;
performing the first oxidation process to form a doped layer in the first cap layer;
removing part of the doped layer and part of the first cap layer to form the first spacer;
performing a second oxidation process to extend the first spacer for forming a second spacer; and
forming an oxide layer on the first cap layer.

8. The method of claim 7, wherein bottom surfaces of the MTJ and the second spacer are coplanar.

9. A magnetoresistive random access memory (MRAM) device, comprising:
a spin orbit torque (SOT) layer on a substrate;
a magnetic tunneling junction (MTJ) on the SOT layer;
a first cap layer adjacent to the MTJ;
a second cap layer adjacent to the first cap layer; and
a spacer between the first cap layer and the second cap layer.

10. The MRAM device of claim 9, further comprising:
an inter-metal dielectric (IMD) layer on the substrate;
the SOT layer on the IMD layer;
a top electrode (TE) on the MTJ;
the first cap layer adjacent to the TE and the MTJ; and
an oxide layer around the second cap layer.

11. The MRAM device of claim 10, wherein a top surface of the TE comprises a curve.

12. The MRAM device of claim 9, wherein a bottom surface of the first cap layer is lower than a bottom surface of the spacer.

13. The MRAM device of claim 9, wherein a bottom surface of the second cap layer is lower than a bottom surface of the spacer.

14. The MRAM device of claim 9, wherein a bottom surface of the second cap layer is lower than a bottom surface of the first cap layer.

15. A magnetoresistive random access memory (MRAM) device, comprising:
a spin orbit torque (SOT) layer on a substrate;
a magnetic tunneling junction (MTJ) on the SOT layer;
a first cap layer adjacent to the MTJ; and
a spacer adjacent to the first cap layer, wherein bottom surfaces of the first cap layer and the spacer are coplanar.

16. The MRAM device of claim 15, further comprising:
an inter-metal dielectric (IMD) layer on the substrate;
the SOT layer on the IMD layer;
a top electrode (TE) on the MTJ;
the first cap layer adjacent to the TE and the MTJ; and
an oxide layer around the spacer.

17. The MRAM device of claim 16, wherein a top surface of the TE comprises a curve.

18. The MRAM device of claim 15, wherein bottom surfaces of the MTJ and the spacer are coplanar.

19. The MRAM device of claim 15, further comprising a doped region in the SOT layer under the spacer.
